(19) United States
(12) Patent Application Publication
(10) Pub. No.: US 2021/0305348 A1
(43) Pub. Date: Sep. 30, 2021

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Weiwei YANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/051,182

(22) PCT Filed: May 25, 2020
(86) PCT No.: PCT/CN2020/092133

§ 371 Date: Oct. 28, 2020

(30) Foreign Application Priority Data
Mar. 31, 2020 (CN) 202010246054.1

(51) Int. Cl. H01L 27/32; H01L 51/00; H01L 51/56

(52) U.S. Cl. CPC H01L 27/3276; H01L 27/3246; H01L 27/3258; H01L 27/3262; H01L 27/1225; H01L 51/56; H01L 2227/323; H01L 2251/5338; H01L 51/0097

(57) ABSTRACT

A display panel and a manufacturing method thereof are provided. The display panel includes a bending area and a non-bending area; a thin film transistor structure layer having a plurality of thin film transistors arranged in an array; at least one groove at least provided in the bending area; an organic filling layer filled in the groove, and a surface of the organic filling layer being higher than a groove opening of the groove; and a plurality of signal lines electrically connected to the thin film transistors, and covering the surface of the organic filling layer to form an uneven wiring structure.

### FIELD OF INVENTION

The present invention relates to technical fields of display panels, and in particular to a display panel and a manufacturing method thereof.

### BACKGROUND OF INVENTION

Organic light-emitting diode (OLED) has more and more applications due to its advantages, such as light weights, self-illumination, wide viewing angles, low driving voltages, high luminous efficiency, low power consumption, and fast response times. Especially, flexible OLED display devices with the bendable and easily portable characteristics has become the main field of research and development in the field of display technology.

FIG. 1a is a schematic cross-sectional structure view of a display panel provided in the prior art. The display panel includes a thin film transistor structure layer 110, a signal line 170, a planarization layer 120, a pixel electrode layer 130, and a pixel definition layer 140. The thin film transistor structure layer 110 includes a substrate 111, a barrier layer 112, a buffer layer 113, an active layer 114, a first gate insulating layer 1151, a first gate electrode layer 1161, a second gate insulating layer 1152, a second gate electrode layer 1162, a interlayer dielectric layer 117, drain electrodes 1181, and source electrodes 1182.

However, the current flexible display devices are easily broken after being bent multiple times, causing abnormal display. Therefore, the structure needs to be optimized urgently.

Therefore, it is necessary to develop a new type of display panel to overcome the defects of the prior art.

### SUMMARY OF INVENTION

### Technical Problem

An object of the present invention is to provide a display panel, which can solve the problems that the flexible display devices in the prior art are easily broken after being bent multiple times, causing abnormal display.

### Technical Solution

In order to achieve the above object, the present invention provides a display panel, including: a bending area and a non-bending area; a thin film transistor structure layer having a plurality of thin film transistors arranged in an array; at least one groove at least provided in the bending area; an organic filling layer filled in the groove, and a surface of the organic filling layer being higher than a groove opening of the groove; and a plurality of signal lines electrically connected to the thin film transistors, and covering the surface of the organic filling layer to form an uneven wiring structure.

Furthermore, in other embodiments, the at least one groove is provided between adjacent two of the thin film transistors; and at least one of the signal lines is bridged between two of the thin film transistors.

Furthermore, in other embodiments, the thin film transistor structure layer includes: a substrate; an active layer disposed on the substrate; a first gate insulating layer disposed on the active layer; a first gate electrode layer disposed on the first gate insulating layer; and a source electrode and a drain electrode disposed on the first gate electrode layer, the source electrode and the drain electrode correspondingly connected to the active layer; wherein each of the thin film transistors has the active layer, the first gate insulating layer, the first gate electrode layer, the source electrode, and the drain electrode.

Furthermore, in other embodiments, the display panel further includes a plurality of data lines arranged parallel to each other; a plurality of scan lines arranged parallel to each other; and the scan lines being in perpendicular to the data lines; wherein the signal lines include: a first bridge line connected between the source electrodes or the drain electrodes of adjacent two of the thin film transistors in a same column, and the first bridge line being parallel to the data line; or/and a second bridge line connected between adjacent two of the thin film transistors of the gate electrode layer in a same row, and the second bridge line being parallel to the scan line.

Furthermore, in other embodiments, the thin film transistor structure layer includes: a second gate insulating layer provided between the first gate electrode layer and the source electrodes; a second gate electrode layer provided between the second gate insulating layer and the source electrodes; a dielectric layer provided between the second gate electrode layer and the source electrodes; and the groove penetrating from a surface of an interlayer dielectric layer to a surface of the substrate.

Furthermore, in other embodiments, the display panel further includes: a planarization layer disposed on the source electrode, the drain electrode and the signal lines; a pixel electrode layer disposed the planarization layer, and the pixel electrode layer connected to the drain; and a pixel definition layer disposed on the pixel electrode layer.

Furthermore, in other embodiments, the groove is located in the non-bending area or the bending area.

Furthermore, in other embodiments, the grooves are discontinuously arranged in a row.

Furthermore, in other embodiments, the groove is provided between adjacent two of the thin film transistors in the same column; or/and the groove is provided between adjacent two of the thin film transistors in the same row.

Another object of the present invention is to provide a manufacturing method for manufacturing the display panel as described in the present invention, the display panel including a bending area and a non-bending area, wherein the manufacturing method includes following steps of: providing a thin film transistor structure layer having a plurality of thin film transistors arranged in an array; forming a groove in the bending area; filling an organic filling layer in the groove, and a surface of the organic filling layer being higher than a groove opening of the groove; and depositing a metal material on the surface of the organic filling layer to form a plurality of uneven signal lines, wherein the signal lines is electrically connected to the thin film transistors.

Furthermore, in other embodiments, in the step of providing the thin film transistor structure layer, the manufacturing method further including steps of: providing a substrate; forming a barrier layer on the substrate; forming a buffer layer on the barrier layer; depositing a semiconductor material on the buffer layer to form an active layer; forming a gate insulating layer on the active layer; depositing a metal material on the gate insulating layer to form a gate electrode layer; forming an interlayer dielectric layer on the gate electrode layer; depositing a metal material on the interlayer dielectric layer and in through holes to form a source-drain electrode layer, wherein the source-drain layer is connected to the active layer through the through holes.

Furthermore, in other embodiments, after the step of depositing the metal material on the surface of the organic filling layer to form the uneven signal lines, the manufacturing method further including steps of: forming a planarization layer on the interlayer dielectric layer and the signal lines; forming a pixel electrode layer on the planarization layer; and forming a pixel definition layer on the pixel electrode layer.

### Beneficial Effect

Compared with the prior art, the beneficial effect of the present invention is that the present invention provides a display panel and a manufacturing method thereof. A groove is provided between adjacent two of thin film transistors in the same column or row, and the groove is filled with an organic filling layer with a great flexibility, so as to reduce the stress concentration during a dynamic bending of the display panel and effectively prevent the crack propagation. An uneven wiring structure of a signal line is formed on a surface of the organic filling layer, and the signal line is electrically connected to adjacent two of the thin film transistors and is connected to the scan line or the data line. Because the surface of the organic filling layer is higher than a groove opening of the groove, the signal line is wavy up and down, which can improve the bending characteristics of the signal line and reduce the risk of signal line breakage.

### DRAWINGS

In order to more clearly explain the technical solutions in the embodiments of the present invention, the accompanying drawings required to use in the description of the embodiments will be briefly introduced below. It apparent that the accompanying drawings in the following description are only some embodiments of the present invention. For those skilled in the art, without paying any creative work, other drawings can be obtained based on these drawings.

FIG. 1a is a schematic cross-sectional structure view of a display panel provided in the prior art.

FIG. 1 is a schematic cross-sectional structural view of a display panel provided by Embodiment 1 of the present invention.

FIG. 2 is a schematic top structural view of the display panel provided by Embodiment 1 of the present invention.

FIG. 3 is a schematic top structural view of grooves provided by Embodiment 1 of the present invention.

FIG. 4 is a schematic top view of the display panel according to Embodiment 1 of the present invention.

FIG. 5 is a flow chart of a manufacturing method of the display panel according to Embodiment 1 of the present invention.

FIG. 6 is a schematic top structural view of grooves provided by Embodiment 2 of the present invention.

FIG. 7 is a schematic cross-sectional structural view of a display panel according to Embodiment 3 of the present invention.

FIG. 8 is a schematic top structural view of the display panel according to Embodiment 3 of the present invention.

FIG. 9 is a schematic top view structure of a display panel provided by Embodiment 4 of the present invention.

Reference numbers in the specific embodiments are as follow:

Display panel—100; non-bending area—101; bending area—102.

Thin film transistor structure layer—110; substrate—111; barrier layer—112.

Buffer layer—113.

Active layer—114; first gate insulating layer—1151; first gate electrode layer—1161.

Second gate insulating layer—1152; Second gate electrode layer—1162.

Interlayer dielectric layer—117; drain electrode—1181; source electrode—1182.

Planarization layer—120; pixel electrode layer—130; pixel definition layer—140.

Groove—150; Organic filling layer—160.

Signal line—170; first bridge line—171; second bridge line—172.

### DETAILED DESCRIPTION OF EMBODIMENTS

The technical solutions in the embodiments of the present invention will be described clearly and completely in conjunction with the accompanying drawings in the embodiments of the present invention. It is apparent that the described embodiments are only a part of the embodiments of the present invention, but not all of the embodiments. Based on the embodiments of the present invention, all other embodiments obtained by those skilled in the art without making any creative works should fall within the protection scope of the present invention.

The specific structural and functional details disclosed herein are merely representative and are for the purpose of describing exemplary embodiments of the present invention. However, the present invention can be implemented in many alternative forms, and should not be interpreted as being limited to the embodiments set forth herein.

### Embodiment 1

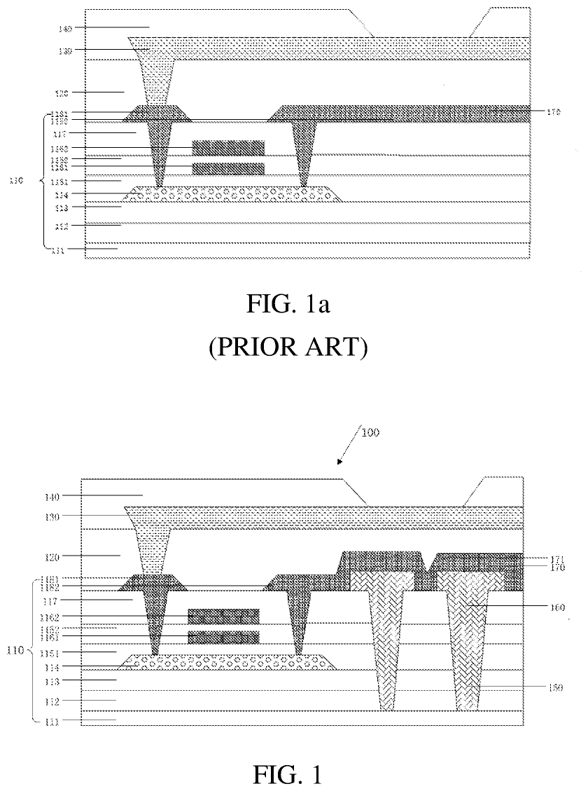

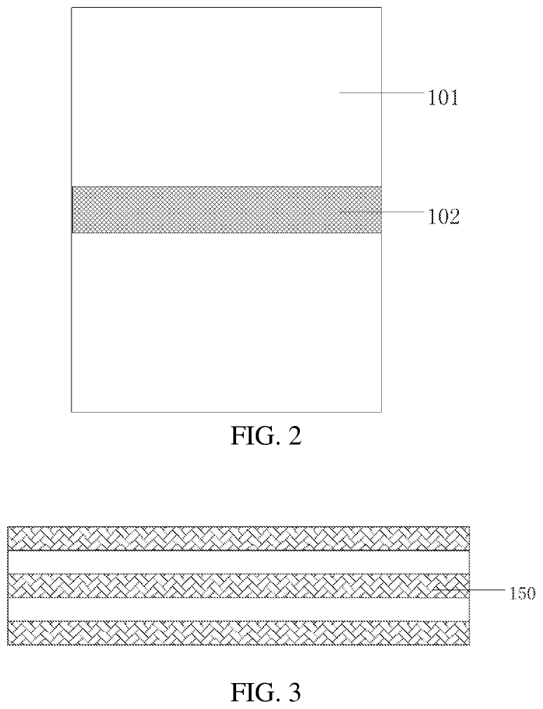

This embodiment provides a display panel. Please refer to FIG. 1 and FIG. 2. FIG. 1 and FIG. 2 are a schematic cross-sectional structural view and a top structural schematic view of a display panel 100 provided by this embodiment, respectively. The display panel 100 includes a bending region 102 and a non-bending region 101, and a thin film transistor structure layer 110, a groove 150, a signal line 170, a planarization layer 120, a pixel electrode layer 130, and a pixel definition layer 140.

The thin film transistor structure layer 110 has thin film transistors distributed in an array, which includes a substrate 111, a barrier layer 112, a buffer layer 113, an active layer 114, a first gate insulating layer 1151, a first gate electrode layer 1161, a second gate insulation layer 1152, a second gate electrode layer 1162, an interlayer dielectric layer 117, a drain electrode 1181, and a source electrode 1182. The barrier layer 112 is disposed on the substrate 111; the buffer layer 113 is disposed on the barrier layer 112; the active layer 114 is disposed on the buffer layer 113; material of the active layer 114 is at least one of indium gallium zinc oxides, and indium zinc tin oxides. The first gate insulating layer 1151 is disposed on the active layer 114; the first gate electrode layer 1161 is disposed on the first gate insulating layer 1151, and material of the first gate electrode layer 1161 is at least one of selecting from a group consisting of molybdenum, aluminum, copper, and titanium. The second gate insulating layer 1152 is disposed on the first gate layer 1161; the second gate electrode layer 1162 is disposed on the second gate insulating layer 1152, and material of the second gate electrode layer 1162 is at least one of selecting from a group consisting of molybdenum, aluminum, copper, and titanium. The interlayer dielectric layer 117 is disposed on the second gate electrode layer 1162, and material of the interlayer dielectric layer 117 is one of selecting from a group consisting of silicon oxide and silicon nitride. The drain electrode 1181 and the source electrode 1182 are disposed on the interlayer dielectric layer 117, the drain electrode 1181 is connected to the active layer 114, and material of the drain electrode 1181 is at least one of selecting from a group consisting of molybdenum, aluminum, copper, and titanium. Each of the thin film transistors has the active layer 114, the first gate insulating layer 1151, the first gate electrode layer 1161, the source electrode 1182, and the drain electrode 1181.

In this embodiment, the groove 150 is located in the bending region 102. In other embodiments, the groove 150 may also be located in the non-bending region 101, which is not limited herein. At least one groove 150 is provided between adjacent two of the thin film transistors. In this embodiment, two grooves 150 are provided between adjacent two of the thin film transistors. The groove 150 is penetrated from a surface of the interlayer dielectric layer 117 and to a surface of the substrate 111.

Please refer to FIG. 3. FIG. 3 is a schematic top view of grooves 150 provided by this embodiment. The grooves 150 are continuously arranged in a row.

The grooves 150 are filled with an organic filling layer 160. The organic filling layer 160 is used an organic material with a great flexibility, which can reduce the stress concentration during dynamic bending of the display panel and effectively prevent crack propagation.

The signal line 170 covers a surface of the organic filling layer 160. In this embodiment, the surface of the organic filling layer 160 is higher than a groove opening of the groove 150, so that the signal line 170 covering on the organic filling layer 160 forms an uneven wiring structure, which can improve the bending characteristics of the signal line and reduce the risk of the signal line breakage.

The display panel includes a plurality of data lines arranged parallel to each other and a plurality of scan lines arranged parallel to each other, and the scan lines being in perpendicular to the data lines.

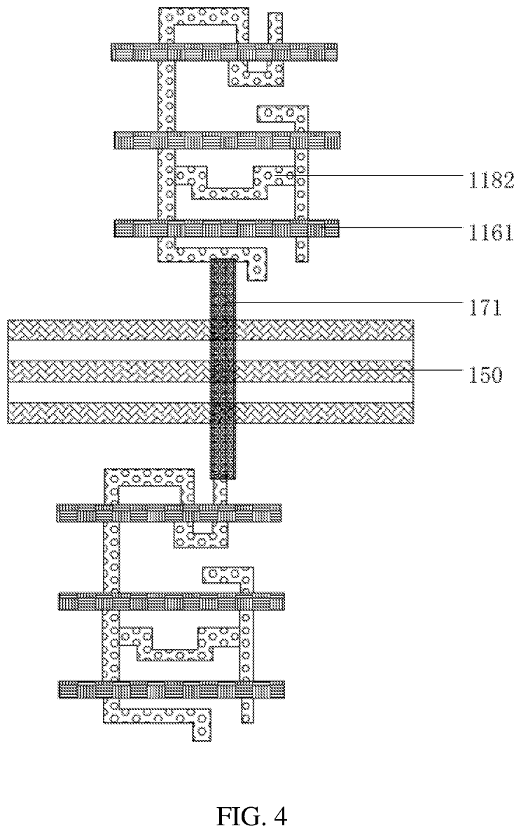

The signal line 170 is a first bridge line 171, which is bridged between two of the thin film transistors. Please refer to FIG. 4. FIG. 4 is a schematic top view of the display panel 100 provided by this embodiment. In this embodiment, a groove 150 is provided between adjacent two of the thin film transistors in the same column, and the first bridge line 171 is connected between the source electrodes 1182 of adjacent two of the thin film transistors in the same column. The first bridge line 171 is parallel to the data line.

This embodiment also provides a manufacturing method for manufacturing the display panel 100 according to this embodiment. The display panel 100 includes a bending area and a non-bending area. The manufacturing method includes steps S1 to S4.

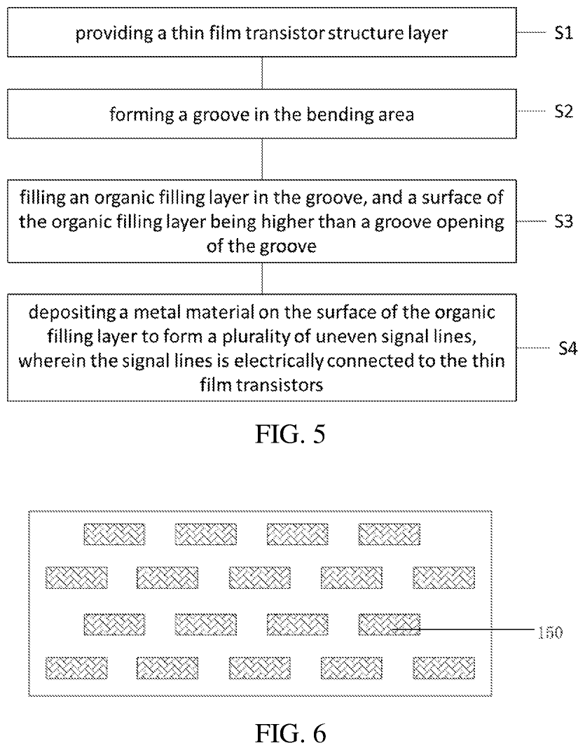

Please refer to FIG. 5, which is a flowchart of a manufacturing method for manufacturing the display panel provided by this embodiment.

A step S1 of providing a thin film transistor structure layer having a plurality of thin film transistors arranged in an array.

The step of providing the thin film transistor structure layer includes steps of: providing a substrate; forming a barrier layer on the substrate; forming a buffer layer on the barrier layer; depositing a semiconductor material on the buffer layer to form an active layer; forming a gate insulating layer on the active layer; depositing a metal material on the gate insulating layer to form a gate electrode layer; forming an interlayer dielectric layer on the gate electrode layer; and depositing a metal material on the interlayer dielectric layer and in through holes to form a source/drain layer, and the source/drain layer connected to the active layer through the through holes.

A step S2 of forming a groove in the bending area.

Two grooves are provided between adjacent two of the thin-film transistors, and the grooves penetrated from a surface of the interlayer dielectric layer and to a surface of the substrate.

A step S3 of filling an organic filling layer in the groove, and a surface of the organic filling layer being higher than a groove opening of the groove.

The organic filling layer uses an organic material with a good flexibility, which can reduce the stress concentration during dynamic bending of the display panel and effectively prevent crack propagation.

A step S4 of depositing a metal material on the surface of the organic filling layer to form a plurality of uneven signal lines, wherein the signal lines is electrically connected to the thin film transistors.

In this embodiment, the surface of the organic filling layer is higher than the groove opening of the groove, so that the signal line covering on the organic filling layer forms an uneven wiring structure, which can improve the bending characteristics of the signal line and reduce the risk of the signal line breakage. The groove is provided between the adjacent two of the thin film transistors in the same column, the first bridge line is connected between the source electrodes of adjacent two thin film transistors in the same column, and the first bridge line is parallel to the data line.

After the step S4, it further includes steps of: forming a planarization layer on the thin film transistor structure layer and the signal lines; forming a pixel electrode layer on the planarization layer; and forming a pixel definition layer on the pixel electrode layer.

### Embodiment 2

A structure of a display panel in this embodiment is similar to the corresponding structure in Embodiment 1. For the same structure, it can refer to the corresponding description in Embodiment 1, which does not be repeated herein. The main difference between the two embodiments is that the grooves 150 are discontinuously arranged in a row. Please refer to FIG. 6. FIG. 6 is a schematic structural view of grooves 150 provided in this embodiment.

Compared with Embodiment 1, the grooves 150 in this embodiment accounts for a smaller proportion in the display panel, and the demand of the organic filling layer filled in the groove 150 is less, which can save the costs.

### Embodiment 3

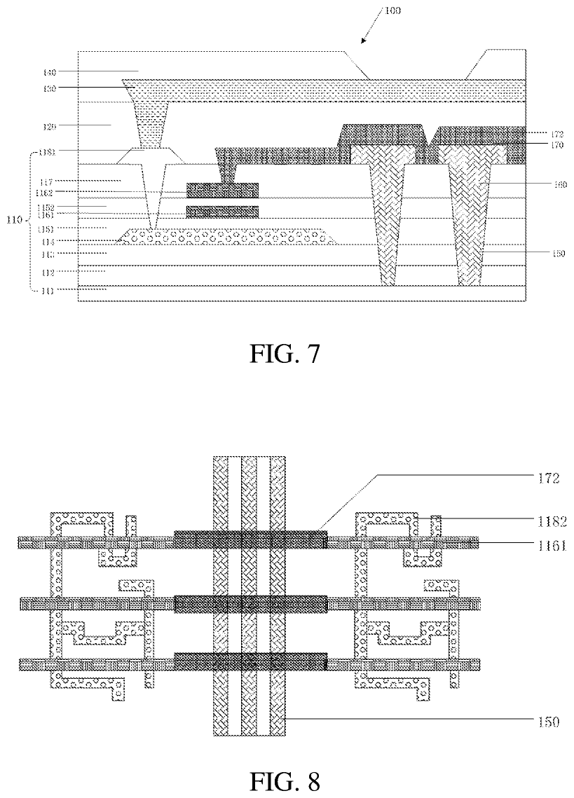

A structure of a display panel in this embodiment is similar to the corresponding structure in Embodiment 1. For the same structure, it can refer to the corresponding description in Embodiment 1, which does not be repeated herein. The main difference between the two embodiments is that the signal line 170 is a second bridge line 172, which is connected between the first gate layers 1161 of adjacent two of the thin film transistors in the same row. Please refer to FIG. 7 and FIG. 8. FIG. 7 is a schematic cross-sectional structural view of the display panel 100 provided by this embodiment, and FIG. 8 is a schematic top structural view of the display panel 100 provided by this embodiment. In this embodiment, the groove 150 is provided between adjacent two thin film transistors in the same row, and the second bridge line 172 is connected between adjacent two of the thin film transistors of the first gate layer 1161 in the same row. The second bridge line 172 is parallel to the scan line.

In other embodiments, the second bridge line 172 is also simultaneously connected between adjacent two of the thin film transistors of the second gate layers 1162 in the same row.

### Embodiment 4

A structure of a display panel in this embodiment is similar to the corresponding structure in Embodiment 1. For the same structure, it can refer to the corresponding description in Embodiment 1, which does not be repeated herein. The main difference between the two embodiments is that the signal line 170 includes a first bridge line 171 and a second bridge line 172, and the first bridge line 171 is connected between the source electrodes 1182 of adjacent two of the thin film transistors in the same column. Concurrently, the second bridge line 172 is connected between adjacent two of the thin film transistors of the first gate layer 1161 in the same row.

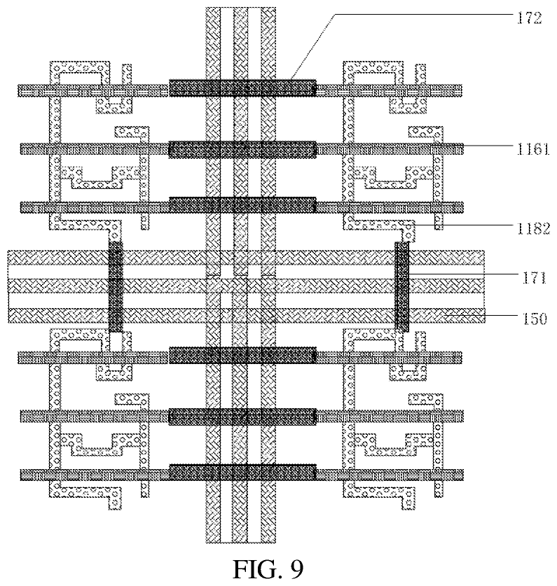

Please refer to FIG. 9, which is a schematic structural view of the display panel 100 provided by this embodiment. In this embodiment, the grooves 150 is provided between adjacent two of the thin film transistors in the same column and between adjacent two of the thin film transistors in the same row. The first bridge line 171 is connected between the source electrodes 1182 of the adjacent two thin film transistors in the same column, and the first bridge line 171 is parallel to the data line. The second bridge line 172 is connected between of adjacent two of the thin film transistors of the first gate layer 1161 in the same row, and the second bridge line 172 is parallel to the scan line.

The beneficial effect of the present invention is that the present invention provides a display panel and a manufacturing method thereof. A groove is provided between adjacent two of thin film transistors in the same column or row, and the groove is filled with an organic filling layer with a great flexibility, so as to reduce the stress concentration during a dynamic bending of the display panel and effectively prevent the crack propagation. An uneven wiring structure of a signal line is formed on a surface of the organic filling layer, and the signal line is electrically connected to adjacent two of the thin film transistors and is connected to the scan line or the data line. Because the surface of the organic filling layer is higher than a groove opening of the groove, the signal line is wavy up and down, which can improve the bending characteristics of the signal line and reduce the risk of signal line breakage.

The above description is only the preferred embodiment of the present invention. It should be pointed out that for those skilled in the art, without departing from the principles of the present invention, several improvements and modifications can be made, and these improvements and modifications should also be regarded as the protection scope of the present invention.

1. A display panel, comprising:
a bending area and a non-bending area;
a thin film transistor structure layer having a plurality of thin film transistors arranged in an array;
at least one groove at least provided in the bending area;
an organic filling layer filled in the groove, and a surface of the organic filling layer being higher than a groove opening of the groove; and
a plurality of signal lines electrically connected to the thin film transistors, and covering the surface of the organic filling layer to form an uneven wiring structure.

2. The display panel according to claim 1, wherein the at least one groove is provided between adjacent two of the thin film transistors; and at least one of the signal lines is bridged between two of the thin film transistors.

3. The display panel according to claim 2, wherein the thin film transistor structure layer comprises:
a substrate;
an active layer disposed on the substrate;
a first gate insulating layer disposed on the active layer;
a first gate electrode layer disposed on the first gate insulating layer; and
a source electrode and a drain electrode disposed on the first gate electrode layer, the source electrode and the drain electrode correspondingly connected to the active layer; wherein each of the thin film transistors has the active layer, the first gate insulating layer, the first gate electrode layer, the source electrode, and the drain electrode.

4. The display panel according to claim 3, wherein the display panel further comprises a plurality of data lines arranged parallel to each other; a plurality of scan lines arranged parallel to each other; and the scan lines being in perpendicular to the data lines;
wherein the signal lines comprise:
a first bridge line connected between the source electrodes or the drain electrodes of adjacent two of the thin film transistors in a same column, and the first bridge line being parallel to the data line; or/and
a second bridge line connected between adjacent two of the thin film transistors of the gate electrode layer in a same row, and the second bridge line being parallel to the scan line.

5. The display panel according to claim 4, wherein the display panel further comprises:
a planarization layer disposed on the source electrode, the drain electrode and the signal lines;
a pixel electrode layer disposed the planarization layer, and the pixel electrode layer connected to the drain electrode; and
a pixel definition layer disposed on the pixel electrode layer.

6. The display panel according to claim 1, wherein the groove is located in the non-bending area or the bending area.

7. The display panel according to claim 1, wherein the grooves are discontinuously arranged in a row.

8. The display panel according to claim 7, wherein the groove is provided between adjacent two of the thin film transistors in the same column; or/and the groove is provided between adjacent two of the thin film transistors in the same row.

9. A manufacturing method for manufacturing the display panel as described in claim 1, the display panel comprising a bending area and a non-bending area, wherein the manufacturing method comprises following steps of:
providing a thin film transistor structure layer having a plurality of thin film transistors arranged in an array;
forming a groove in the bending area;
filling an organic filling layer in the groove, and a surface of the organic filling layer being higher than a groove opening of the groove; and
depositing a metal material on the surface of the organic filling layer to form a plurality of uneven signal lines, wherein the signal lines is electrically connected to the thin film transistors.

10. The manufacturing method according to claim 9, wherein after the step of depositing the metal material on the surface of the organic filling layer to form the uneven signal lines, the manufacturing method further comprising steps of:
forming a planarization layer on the thin film transistor structure layer and the signal lines;
forming a pixel electrode layer on the planarization layer; and
forming a pixel definition layer on the pixel electrode layer.

11. The manufacturing method according to claim 9, wherein the at least one groove is provided between adjacent two of the thin film transistors; and at least one of the signal lines is bridged between two of the thin film transistors.

12. The manufacturing method according to claim 9, wherein the grooves are discontinuously arranged in a row.

13. The manufacturing method according to claim 9, wherein the groove is provided between adjacent two of the thin film transistors in the same column; or/and the groove is provided between adjacent two of the thin film transistors in the same row.

14. A display device, comprising the display panel as described in claim 1.

15. The display device according to claim 14, wherein the thin film transistor structure layer comprises:
a substrate;
an active layer disposed on the substrate;
a first gate insulating layer disposed on the active layer;
a first gate electrode layer disposed on the first gate insulating layer; and
a source electrode and a drain electrode disposed on the first gate electrode layer, the source electrode and the drain electrode correspondingly connected to the active layer; wherein each of the thin film transistors has the active layer, the first gate insulating layer, the first gate electrode layer, the source electrode, and the drain electrode.

16. The display device according to claim 15, wherein the display device further comprises a plurality of data lines arranged parallel to each other;
a plurality of scan lines arranged parallel to each other; and the scan lines being in perpendicular to the data lines;
wherein the signal lines comprise:
a first bridge line connected between the source electrodes or the drain electrodes of adjacent two of the thin film transistors in a same column, and the first bridge line being parallel to the data line; or/and
a second bridge line connected between adjacent two of the thin film transistors of the gate electrode layer in a same row, and the second bridge line being parallel to the scan line.

17. The display device according to claim 16, wherein the display device further comprises:
a planarization layer disposed on the source electrode, the drain electrode and the signal lines;
a pixel electrode layer disposed the planarization layer, and the pixel electrode layer connected to the drain electrode; and
a pixel definition layer disposed on the pixel electrode layer.

18. The display device according to claim 14, wherein the groove is located in the non-bending area or in the bending area.

19. The display device according to claim 14, wherein the grooves are discontinuously arranged in a row.

20. The display device according to claim 14, wherein the groove is provided between adjacent two of the thin film transistors in the same column; or/and the groove is provided between adjacent two of the thin film transistors in the same row.
